(19) United States
(12) Patent Application Publication
(10) Pub. No.: US 2022/0101089 A1
(43) Pub. Date: Mar. 31, 2022

(54) METHOD AND APPARATUS FOR NEURAL ARCHITECTURE SEARCH

(71) Applicant: SAMSUNG ELECTRONICS CO., LTD., Suwon-si (KR)

(72) Inventors: Mohamed Saied Abdelkader ABDELFATTAH, Staines (GB); Abhinav MEHROTRA, Staines (GB); Lukasz DUDZIAK, Staines (GB)

(21) Appl. No.: 17/477,851

(22) Filed: Sep. 17, 2021

Related U.S. Application Data
(63) Continuation of application No. PCT/KR2021/012407, filed on Sep. 13, 2021.

(30) Foreign Application Priority Data
Sep. 25, 2020 (GB) 2015231.0

(51) Int. Cl. G06N 3/04; G06F 17/18; G06N 3/08

(52) U.S. Cl. CPC G06N 3/04; G06N 3/08; G06F 17/18

(57) ABSTRACT

The disclosure relates to methods, apparatuses and systems for improving a neural architecture search (NAS). For example, A computer-implemented method using a searching algorithm to design a neural network architecture is provided, the method including: obtaining a plurality of neural network models; selecting a first subset of the plurality of neural network models; applying the searching algorithm to the selected subset of models; and identifying an optimal neural network architecture by repeating the selecting and applying for a fixed number of iterations; wherein at least one score indicative of validation loss for each model is used in or alongside at least one of the selecting and applying.

### CROSS-REFERENCE TO RELATED APPLICATIONS

This application is a continuation of International Application No. PCT/KR2021/012407 designating the United States, filed on Sep. 13, 2021, in the Korean Intellectual Property Receiving Office and claiming priority to UK Patent Application No. 2015231.0, filed on Sep. 25, 2020, in the UK Patent Office, the disclosures of which are incorporated by reference herein in their entireties.

### BACKGROUND

### Field

The disclosure relates to computer technology and, for example, to a method and apparatus for neural architecture search.

### Description of Related Art

Neural architecture search (NAS) can automatically design competitive neural networks compared to hand-designed alternatives. Examples of NAS are described in “Efficient architecture search by network transformation” by Cai et al published in Association for the Advancement of Artificial Intelligence in 2018 and “Neural architecture search with reinforcement learning” by Zoph et al in International Conference on Learning Representations (ICLR) in 2017.

For example, standard NAS may be expressed as trying to solve the problem:

$${a}^{*} = arg {max}_{a ∈ A} {L}_{val} ( a , {W}_{a}^{*} )$$

$$s . t . \\ {W}_{a}^{*} = arg {max}_{{W}_{a}} {L}_{train} ( a , {W}_{a} )$$

where:
Lᵥₐₗ is validation loss, Lₜᵣₐᵢₙ is training loss, a is an architecture from the predefined search space A (set of architecture which is considered when searching) and Wₐ are weights for architecture a. Lₐ may be used as a shorthand of Lᵥₐₗ (a, Wₐ*) as in the description below.

Training all models in A is infeasible and thus, NAS is usually implemented as an iterative process where in each iteration some models are trained in order to get their Lᵥₐₗ values, which are later used to influence selection of further models, which are then again trained, and so on. Being given a maximum number of models which can be trained (T) and a searching function which proposes new architectures (being given history of previous ones), the problem becomes:

$${a}_{t} = \{ \begin{matrix}search ( {θ}_{0} ) & if t = 1 \\ search ( {θ}_{t - 1} , {a}_{1} , {a}_{2} , … , {a}_{t - 1} ) & otherwise\end{matrix} \\ τ ( T ) = ( {a}_{1} , {a}_{2} , … , {a}_{T} ) \\ {a}^{*} \approx arg {max}_{a ∈ τ ( T )} {L}_{a}$$

where τ(t) is the sequence of the first t models selected by the searching algorithm, aₜ is an architecture selected at iteration t, and θₜ is state of the searching algorithm after selecting model aₜ.

As mentioned above, most of the searching algorithms involve some kind of (more-or-less) expensive training of each model in order to decide on the next one. For example, an algorithm based on REINFORCE can use the following searching policy:

search(θ,a₁,a₂, . . . ,aₜ₋₁)=sample(π_{θ}*)

where: θ*=θ+α∇_{θ} log π_{θ}(aₜ₋₁)Lₐ_{ₜ₋₁}

where π is a parametrized distribution, θ is the parameters of the distribution, aₜ is the model at iteration t, and Lₐ_{ₜ₋₁} may be used as a shorthand of Lᵥₐₗ(aₜ₋₁, Wₐ*) and α is a constant.

In other words, each time a new model is to be selected by the algorithm, a parametrized distribution π is sampled. To take into account performance of the previously selected models, before sampling, the parameters θ of the distribution are updated by considering Lᵥₐₗ of the previous model (aₜ₋₁). As mentioned above, obtaining Lᵥₐₗ of models is expensive, which makes the entire searching process limited mostly by evaluating the element in bold: Lₐ_{ₜ₋₁}

### SUMMARY

Embodiments of the disclosure provide an improved way of to evaluate validation loss when conducting a neural architecture search (NAS).

According to an example embodiment, there is provided a computer-implemented method using a searching algorithm to design a neural network architecture, the method comprising: obtaining a plurality of neural network models; selecting a first subset of the plurality of neural network models; applying the searching algorithm to the selected subset of models; and identifying an optimal neural network architecture by repeating the selecting and applying for a fixed number of iterations; wherein a score indicative of validation loss for each model is used in or alongside at least one of the selecting and applying steps.

### BRIEF DESCRIPTION OF THE DRAWINGS

The above and other aspects, features and advantages of certain embodiments of the present disclosure will be more apparent from the following detailed description, taken in conjunction with the accompanying drawings, in which:

FIG. 1 is a flowchart illustrating an example method using a searching algorithm to design a neural network architecture according to various embodiments;

FIG. 2 is a graph plotting the average best test accuracy against the number of trained models according to various embodiments;

FIG. 3 is a graph plotting the average best test accuracy against the number of trained models according to various embodiments;

FIG. 4 is a graph plotting the average best test accuracy against the number of trained models according to various embodiments; and

FIG. 5 is a block diagram illustrating an example configuration of a server according to various embodiments.

### DETAILED DESCRIPTION

The searching algorithm may include any appropriate algorithm and may include an algorithm which uses artificial intelligence or machine learning. For example, the searching algorithm may be selected from Aging Evolution, REINFORCE with LSTM-based policy network, Random search, GCN-based binary predictor but is not limited to these algorithms Typically each selected model is trained when applying the searching algorithm during a neural architecture search and thus applying the searching algorithm may comprise training each selected model. This training will typically use a task-specific dataset, e.g. if the algorithm is searching for the best image classification model, a dataset like Imagenet might be used to train models during NAS. A full dataset may have millions of examples and during full training, the method might be required to iterate over the entire dataset multiple times.

For example, when using the aging evolution algorithm, the selecting step may comprise mutating models whereby mutations are inherent to the selection mechanism. The score may be calculated for each of possible mutations and may be used to rank the models to aid in the next selecting step. Each selected model may be trained.

The search algorithm may use a predictor to find the accuracy (or other performance metric) of the model although it is noted that many existing NAS algorithms do not rely on predictions. The predictor may be trained and this training may be different from the training mentioned above. For example, the training above may comprise training a few models and then the predictor may be trained to predict the performance metric of models in the selected set of models without training them.

The score may be obtained using an approximate scoring function. For example, the score may be obtained by calculating a gradient of a training loss function. The score may be obtained for a single batch of data, e.g., for a relatively small subset of the dataset. Usual batch sizes in machine learning tasks typically vary between 10-1000 examples (compared to the millions of examples in the full dataset). As explained above, during full training we may iterate over the entire dataset multiple times. In contrast, in this example for obtaining the score, only take a single batch is taken and used only once. The batch of data may refer to a subset of training data which would normally be used to train models during NAS.

The neural network architecture may comprise a plurality of parameters, e.g., input, output, the nature of the layers or operations, e.g., a 3×3 convolutional layer, a 1×1 convolutional layer. The score may be obtained by calculating an individual score for each parameter within a selected neural network architecture. The individual scores may be aggregated, e.g., summed or otherwise combined to obtain a global score for the selected neural network architecture.

The score may be calculated using, for example, and without limitation, at least one of the following methods: single-shot network pruning (SNIP), gradient signal preservation (GRASP), synaptic flow, Jacobian covariance, L2 norm, gradient norm and Fisher information. For example, the score may be calculated using synaptic flow which assigns scores S to all the parameters within the architecture as:

$$S ( W ) = \frac{\partial {L}_{train}}{\partial W} ⊙ W$$

where Lₜᵣₐᵢₙ is the training loss and W is the weights. The overall network score may thus be determined:

$${S}_{a} = {\sum }_{i} {S ( {W}_{a} )}_{i}$$

where Sₐ is the overall network score for a particular architecture a and Wₐ are the weights for architecture a.

Prior to selecting the first subset, the method may, for example, comprise selecting a sample of the plurality of neural network models, obtaining the score which is indicative of validation loss for each model in the sample, and ranking the models within the sample based on the obtained score. The first subset may then be selected from the ranked models, e.g. by selecting the highest ranked models. The sample is preferably larger (e.g., may contain more models) than any subset but may be smaller than the total number of the plurality of models. The sample may be selected randomly. Such a sample selection may be referred to as a warm-up phase.

Obtaining the score may comprise calculating multiple scores for each model in the sample. For example, at least three of the scores may be selected from the group comprising single-shot network pruning (SNIP), gradient signal preservation (GRASP), synaptic flow, Jacobian covariance, L2 norm, gradient norm and Fisher information. The method may further comprise ranking the models by ranking a first model higher than a second model when a majority of the multiple scores indicate that the first model is better than the second model.

Prior to selecting the first subset, the method may comprise selecting a first sample of the plurality of neural network models, obtaining the score which is indicative of validation loss for each model in the first sample, ranking the models within the first sample based on the obtained score, selecting a second sample from the first sample, obtaining the score which is indicative of validation loss for each model in the second sample, and ranking the models within the second sample based on the obtained score. The first subset may be selected from the ranked models within the second models.

The method may comprise obtaining the score which is indicative of validation loss in the applying (training) step and using the obtained scores to inform the selection of a subsequent subset of the plurality of neural network models. Obtaining the score may comprise calculating multiple scores (e.g. from using at least two of single-shot network pruning (SNIP), gradient signal preservation (GRASP), synaptic flow, Jacobian covariance, L2 norm, gradient norm and Fisher information) for each model in the subset.

The method may further comprise obtaining a performance metric for each model in the subset and comparing the obtained performance metric with each of the multiple scores to determine which of the multiple scores correlates with the obtained performance metric. Different performance metrics may be output as desired and may include one or more of accuracy, latency, energy consumption, thermals and memory utilization. It may not be necessary to obtain an absolute value for the performance and it may be sufficient to compare the performances of models so the performance metric may be a ranking of the model based on performance By correlating the score with the performance metric, e.g., by determining whether both the score and the performance metric agree on the performance of one model relative to another, the method can learn which scores are more useful.

The method may further comprise selecting one or more metrics based on the correlation. The selected one or more metrics may be used to calculate a next score.

The method may comprise obtaining the score which is indicative of validation loss in the applying step and using the obtained scores to inform the selection of a subsequent subset of the plurality of neural network models.

The score which is indicative of validation loss for each model in the sample and the score which is indicative of validation loss in the applying step may be calculated using at least one different metric.

The method may further comprise obtaining the score which is indicative of validation loss alongside the applying (training) step; obtaining a performance metric for each model in the subset and using both the obtained score and performance metric to identify the optimal neural network architecture. In this way, the score may be considered to be exposing additional information alongside a traditional NAS algorithm. Such a method may be considered an augmentation of a normal NAS algorithm.

The neural network model may include a deep neural network. Examples of neural networks include, but are not limited to, convolutional neural network (CNN), deep neural network (DNN), recurrent neural network (RNN), restricted Boltzmann Machine (RBM), deep belief network (DBN), bidirectional recurrent deep neural network (BRDNN), generative adversarial networks (GAN), and deep Q-networks. For example, a CNN may include different computational blocks or operations selected from conv1×1, conv3×3 and pool3×3.

The method described above may be wholly or partly performed on an apparatus, e.g., an electronic device or server, using a machine learning or artificial intelligence model. In a related approach of the disclosure, there is provided a non-transitory data carrier carrying processor control code to implement the methods described herein when executed by a processor.

The disclosure relates to methods, apparatuses and systems for predicting the performance of a neural network model on a hardware arrangement and of searching for an optimal result based on the performance.

Warmup, move proposal, and augmentation described in this disclosure may be independent procedures, but may be performed using the results of other procedures. Each procedure may be repeated multiple times. Various combinations of each operation described in the disclosure may exist.

As explained in the background section, neural architecture search (NAS) is usually implemented as an iterative process where in each iteration some models are trained in order to get the Lᵥₐₗ (validation loss) values, which are later used to influence selection of further models and so on. This iterative approach shares some objectives and problems with the problem of neural network pruning and the specific ideas described in this document are especially related to the “pruning before training” line of research. Obtaining validation loss values is typically expensive and the entire searching process is limited by evaluating this element. The disclosure relates to improving sample-efficiency of automated NAS by considering a number of (relatively) cheap “scoring” or “proxy” functions which can be used to compare different neural networks (e.g., tell which one can achieve better performance) without having to undergo full training. These “scoring” functions may be considered to be alternatives to Lᵥₐₗ which are cheaper to evaluate, avoid expensive training and thus potentially speed up the searching process.

In the disclosure, a cheap metric may refer, for example, to a fast metric or a metric with a small amount of computation. Expensive may have a contrasting meaning to cheap.

Examples of various “scoring” or “proxy” functions/metrics are described in the following documents and these publications are incorporated by reference herein in their entireties:

| Label | Publication title & author | Publication Reference |
|---|---|---|
| SNIP | “Single-shot Network Pruning based on Connection | https://arxiv.org/abs/1810.02340 |
| | Sensitivity” by Lee et al | |
| GRASP | “Picking Winning Tickets Before Training by Preserving | https://arxiv.org/abs/2002.07376 |
| | Gradient Flow” by Wang et al | |
| Synaptic flow | Pruning neural networks without any data by iteratively | https://arxiv.org/abs/2006.05467 |
| | conserving synaptic flow by Tanaka et al | |
| Jacobian | Neural Architecture Search without Training by Mellor | https://arxiv.org/abs/2006.04647 |
| covariance | et al | |
| L2 norm | L2 Regularization for Learning Kernels By Cortes et al | https://arxiv.org/abs/1205.2653 |
| Fisher | Faster gaze prediction with dense networks and Fisher | https://arxiv.org/abs/1801.05787 |
| information: | pruning By Theis et al | |

Another function which is similar to L2 norm is “gradient norm”. This focuses on gradient rather than weights.

Coming from the pruning work, these metrics operate on a per-parameter basis assigning scores for all parameters in a neural network. In this new methodology, a global score for the neural network is used and this is obtained by summing up all individual scores.

For example, given a set of neural network weights W, the third example above, synaptic flow assigns scores S to all of them as:

$$S ( W ) = \frac{\partial {L}_{train}}{\partial W} ⊙ W$$

In this proposed methodology, the overall network score may thus be:

$${S}_{a} = {\sum }_{i} {S ( {W}_{a} )}_{i}$$

where Sₐ is the overall network score for a particular architecture a and Wₐ are the weights for architecture a.

The metrics considered from the papers and examples above are cheap to compute (compared to full training of a model) and usually involve calculating gradient of the training loss function for a single batch of data, thus giving us a way of indicating a network's performance in a much cheaper way than full training (which usually requires us to compute gradient for thousands—or even more—input batches). The resulting searching process may be referred to, for example, as a lightweight NAS.

As explained in greater detail below, the proposed score or metric (the terms may be used interchangeably) which is calculated above may be used in a number of well-known NAS algorithms in different ways to help the NAS algorithms achieve better results while using less computational overhead. As examples, the following algorithms are considered: Aging Evolution, REINFORCE with LSTM-based policy network, Random search, GCN-based binary predictor. Three different ways of using the metrics are discussed and are termed: warmup, move proposal, augmentation. The disclosure also considers usage of a single, selected metric or an ensemble of metrics with majority voting or expert gating.

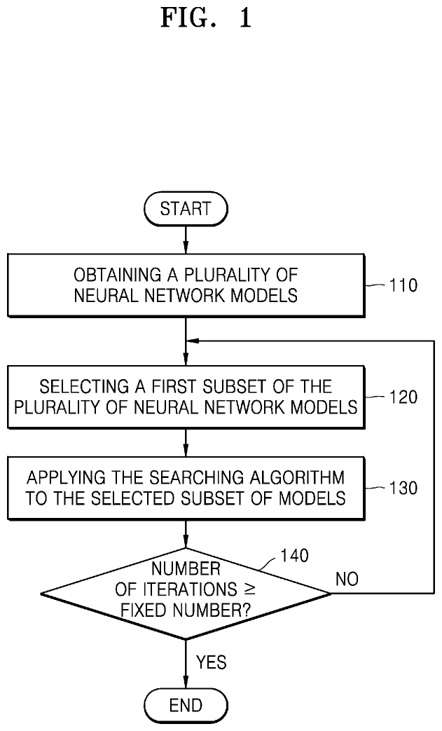

Various operations in using a searching algorithm to design a neural network architecture are illustrated in FIG. 1. The operations include, for example, obtaining a plurality of neural network models 110, selecting a first subset of the plurality of neural network models 120, applying the searching algorithm to the selected subset of models 130, and repeating the selecting and applying steps for a fixed number of iterations to identify an optimal neural network architecture 140.

When the proposed metrics are used for warming up a searching algorithm, that usually involves calculating them for a relatively large number of models (compared to how many models we can afford to train) in order to provide the searching algorithm with a better starting point. For example: in the case of random search, which simply returns random architecture, warming up may be implemented by simply sorting models according to the proposed metrics and later, instead of returning them randomly, those with better scores are considered first. The proposed metrics for warming up may be called warmup, warmup arrangement or warmup approach.

As described above, the problem may be formulated as:

$${a}_{t} = \{ \begin{matrix}search ( {θ}_{0} ) & if t = 1 \\ search ( {θ}_{t - 1} , {a}_{1} , {a}_{2} , … , {a}_{t - 1} ) & otherwise\end{matrix} \\ τ ( T ) = ( {a}_{1} , {a}_{2} , … , {a}_{T} ) \\ {a}^{*} \approx arg {max}_{a ∈ τ ( T )} {L}_{a}$$

In this warmup arrangement, a₁ will thus become the point with the higher score, a₂ will be the second highest, and so on. Sometimes the search space is so large that all of the models within it cannot possibly be sorted (even when using a cheap metric).

According to an embodiment, a method of warming up the searching algorithm, the warmup arrangement, may include sampling N models from the search space of A models, computing one or more metrics to obtain the score for the N models, sorting the N models based on the metric (for example, ranking the models based on the score) and selecting T top models out of N models. An example of warmup with evolution search may refer, for example, to using the T models for the initial evolution pool. Even though N might be much smaller than the total number of models in the search space, it is still usually much higher than the maximum number of models that can be trained, e.g.: T«N«|A|.

According to an embodiment, the warmup arrangement may be performed one or more times using one or more metrics. According to an embodiment, the warmup arrangement may start with a large number of warmup models, then use fewer models. According to an embodiment, the warmup arrangement may start with a cheaper metric and a large number of warmup models, then use more a expensive metric and fewer models.

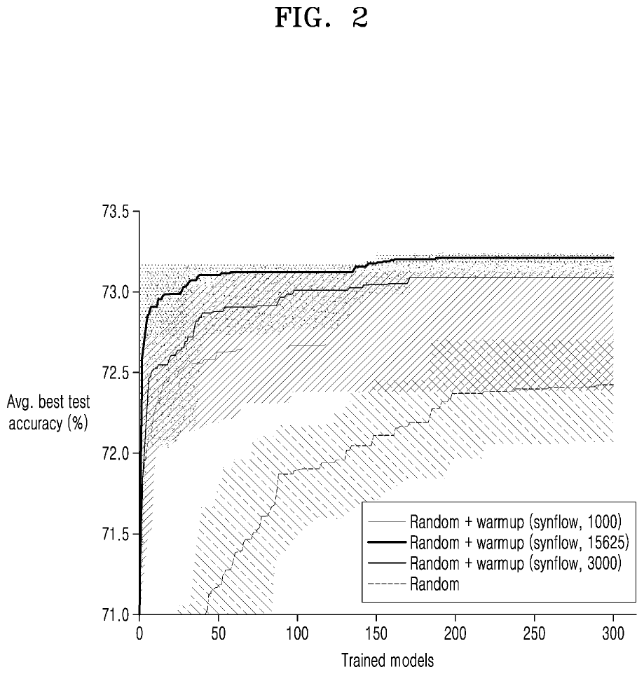

FIG. 2 is a graph plotting the accuracy of the best found model as a function of T, e.g., number of trained models, according to various embodiments. The graph compares a standard random search approach with a warmup approach applied to random search using a synaptic flow metric and varying numbers of sample N models (between 1000 and 15625). For example, each point in the graph was run 30 times. The lines represent the average result and a shaded area lower bound represents the 25th quartile and an upper bound represents the 75th quartile. The results are based on the Nasbench201 benchmark and CIFAR100 dataset. The warmup approach reduces the number of trained models required to achieve a high level for the average best test accuracy. As the number of sample models is increased, the warmup approach also improves.

According to an embodiment, usage of the metrics may be incorporated while searching to make more informed decisions about what model to train next. This may be termed a move approach. For example, the Aging Evolution algorithm works by randomly mutating a semi-randomly selected model from a population of models (similarly to the standard evolution algorithms) However, instead of mutating the selected model randomly, possible mutations could be considered and ranked using the cheap metrics to later choose the most promising one.

According to an embodiment, the move approach may include selecting T models, computing one or more metrics for the T models, sorting the T models from best to worst according to the one or more metrics, and selecting one or more top models based on the sorting.

According to an embodiment, the move approach may be performed using the T models selected from the N models in the warmup arrangement. The score may be calculated using the same or different metrics in the warmup arrangement and the move approach.

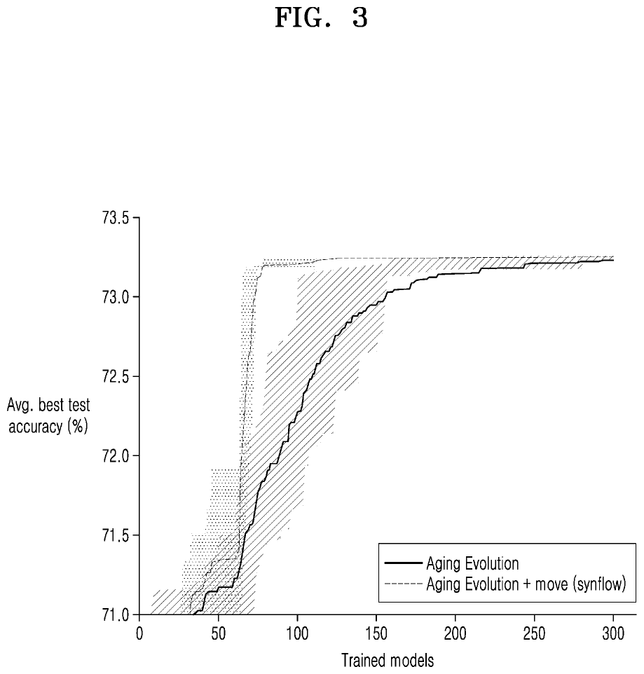

FIG. 3 is a graph plotting the accuracy of the best found model as a function of T, e.g., number of trained models according to various embodiments. The graph compares a standard aging evolution search with a move approach using a synaptic flow metric applied to the aging evolution search. The gain from proposing mutations is visible after initial 64 models are trained randomly (initial population). For example, each point in the graph was run 30 times. The lines represent the average result and the shaded area lower bound represents the 25th quartile and the upper bound represents the 75th quartile. The results could further be improved by combining the warmup approach with the move proposal but FIGS. 2 and 3 are presented separately to clearly show the difference between the two approaches.

Some NAS algorithms might benefit from simply exposing additional information about the models. Thus, the computed metrics may be used as parallel inputs to the searching algorithm (along the model itself) and this approach may be termed an augmentation. For example, a binary GCN predictor can be used to predict relative performance of two models and could further be used to identify good models in a search space by comparing different pairs of models in order to produce their sorted ordering. The predictor, in its normal form, is given a graphical representation of a neural network and tries to predict its (relative) performance

According to an embodiment, the computed metrics could be used alongside the graphical representation of a model as inputs to the predictor in order to provide it with more information about the input mode. It is noted that a graph encodes structure of a neural network but does not include any information about weights etc. On the other hand the proposed metrics may be a form of “impulse response” of the network when given a random input from the training set, so the two approaches are very much complementary to each other.

According to an embodiment, in predicting model performance using a predictor, the input of that predictor may be a description of the model. The description of the model may include at least one graph structure of the model, types of operations, and a cheap metric.

The disclosed metrics are simply approximations of network performance. Therefore optimizing towards them might not always be correlated to optimizing towards finding better models. For example, different metrics may have a different correlation to the final test accuracy when considered with different search spaces/tasks. Consequently, when trying to use a badly correlated metric to improve NAS results, the original performance may actually be degraded.

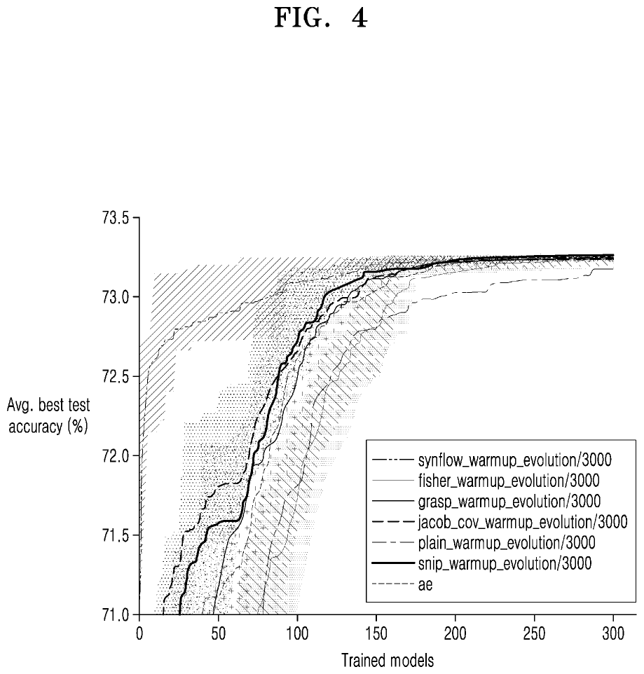

FIG. 4 is a graph plotting the accuracy of the best found model as a function of T, e.g., number of trained models, according to various embodiments. FIG. 4 shows how the performance of the Aging Evolution algorithm changes when using different metrics to warm it up (using N=3000). For example, each point in the graph was run 30 times. The lines represent the average result and the shaded area lower bound represents the 25th quartile and the upper bound represents the 75th quartile. The different metrics are described in the table above. As can be seen, several of the metrics do not change the results significantly. However, some of them (Fisher and Plain) actually make the results worse.

It may be possible to alleviate the problem described above using multiple metrics together. For example, this can be done in a number of different ways.

For example, generally in the case of the warmup approach (but not limited to), a number or plurality of metrics may be calculated for each model. When sorting the models, a voting mechanism can be incorporated to decide which model is better. For example, model A is considered better than model B, if the majority of the plurality of metrics agree that it is better. For example, the plurality of metrics may include three metrics, e.g. synaptic flow, Jacobian covariance and snip metrics and a majority is thus two metrics. Such a three-way voting mechanism has been shown to achieve better correlation with respect to the final accuracy than any metric alone, as highlighted in the table below (showing spearman-ρ correlation).

| Dataset | Grad_norm | SNIP | GRASP | fisher | synflow | Jacob_cov | vote |
|---|---|---|---|---|---|---|---|
| CIFAR-10 | 0.577 | 0.579 | 0.480 | 0.361 | 0.737 | 0.732 | 0.816 |
| CIFAR-100 | 0.635 | 0.633 | 0.537 | 0.388 | 0.763 | 0.706 | 0.834 |
| ImageNet 16-120 | 0.579 | 0.579 | 0.563 | 0.329 | 0.751 | 0.708 | 0.816 |

Generally, in the case of the move (but not limited to), initially all of the selected metrics may be considered and as feedback about the accuracy of the selected models is obtained, this may be correlated with the metrics on-the-fly to learn which ones are more useful than the others (similar to learning a gating function in mixture of experts)

According to an embodiment, the move may additionally include the following steps: evaluating accuracy for at least one of the T models, computing one or more cheap metrics to obtain the score for the at least one of the T models, selecting one or more metrics that correlate well with an accuracy of the at least one of the T models, and using the selected one or more metrics for the next round of the move proposal or calculating the score.

According to an embodiment, the searching algorithm may use both accuracies for the T models and the score which is indicative of validation loss alongside the T models to identify the optimal neural network architecture.

In the case of augmentation, it may not be necessary to consider multiple metrics. However, it may be useful to provide the searching algorithm with more information—a good algorithm will be free to either utilize them or not based on how useful they are. For example, internally, the algorithm might use something similar to the “correlation on-the-fly” described above or can use something completely different.

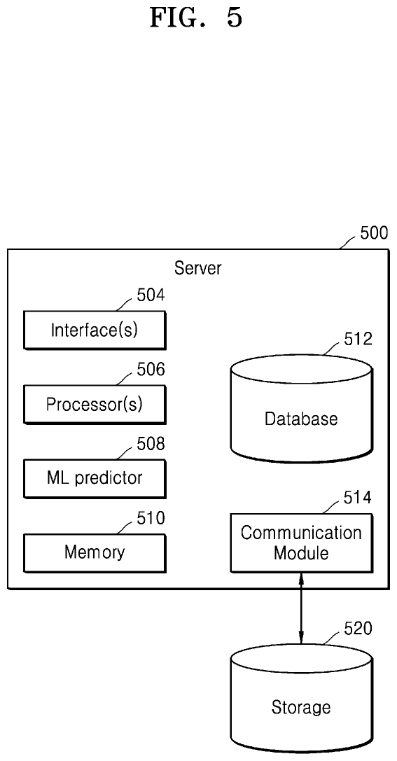

FIG. 5 is a block diagram illustrating an example configuration of a server 500 according to various embodiments. The server 500 may comprise one or more interfaces 504 including various interface circuitry that enable the server 500 to receive inputs and/or provide outputs. For example, the server 500 may comprise a display screen to display the results of the NAS. The server 500 may comprise a user interface for receiving, from a user, a query to conduct a NAS.

The server 500 may comprise at least one processor or processing circuitry 506. The processor 506 may include various processing circuitry and controls various processing operations performed by the server 500. The processor may comprise processing logic to process data and generate output data/messages in response to the processing. The processor may comprise, for example, and without limitation, one or more of a microprocessor, a microcontroller, and an integrated circuit. Optionally, where the searching algorithm using machine learning and predicts performance, the processor may implement at least part of a machine learning predictor 508 on the server 500. The machine learning (ML) predictor 508 may include various processing circuitry and/or executable program instructions and be used to predict performance of a neural network architecture during the NAS. The processor may perform warmup, move proposal, and augmentation. The at least one machine learning predictor 508 may be stored in memory 510.

The server 500 may comprise memory 510. Memory 510 may comprise a volatile memory, such as random access memory (RAM), for use as temporary memory, and/or non-volatile memory such as Flash, read only memory (ROM), or electrically erasable programmable ROM (EEPROM), for storing data, programs, or instructions, for example.

The server 500 may comprise a communication module 514 including various communication circuitry to enable the server 500 to communicate with other devices/machines/components (not shown), thus forming a system. The communication module 514 may be any communication module suitable for sending and receiving data. The communication module may communicate with other machines using any suitable technique, e.g. wireless communication or wired communication techniques. It will also be understood that intermediary devices (such as a gateway) may be located between the server 500 and other components in the system, to facilitate communication between the machines/components.

The server 500 may be a cloud-based server. Where the searching algorithm requires training, a training data set may be used and may be stored in database 512 and/or storage 520. Storage 520 may be remote (e.g., separate) from the server 500 or may be incorporated in the server 500. The search space for the NAS may be stored in database 512 and/or storage 520.

While the disclosure has been illustrated and described with reference to various example embodiments, it will be understood that the various example embodiments are intended to be illustrative, not limiting. It will be further understood by those skilled in the art that various changes in form and detail may be made without departing from the true spirit and full scope of the disclosure, including the appended claims and their equivalents.

What is claimed is:

1. A computer-implemented method using a searching algorithm to design a neural network architecture, the method comprising
obtaining a plurality of neural network models;
selecting a first subset of the plurality of neural network models;
applying the searching algorithm to the selected subset of models; and
identifying an optimal neural network architecture by repeating the selecting and applying for a fixed number of iterations;
wherein at least one score indicative of validation loss for each model is used in or alongside at least one of the selecting and applying.

2. The method of claim 1, wherein the at least one score is obtained by calculating a gradient of a training loss function.

3. The method of claim 1, wherein the neural network architecture comprises a plurality of parameters and the at least one score is obtained by calculating an individual score for each parameter within a selected neural network architecture and aggregating the individual scores to obtain a global score for the selected neural network architecture.

4. The method of claim 1, wherein the at least one score is calculated using at least one of: single-shot network pruning, gradient signal preservation, synaptic flow, Jacobian covariance, L2 norm, gradient norm, and Fisher information.

5. The method of claim 1, further comprising
selecting a sample of the plurality of neural network models,
obtaining the at least one score indicative of validation loss for each model in the sample, and
ranking the models within the sample based on the obtained at least one score,
wherein the first subset is selected from the ranked models.

6. The method of claim 5, wherein the obtaining the at least one score comprises calculating multiple scores for each model in the sample, and wherein the ranking the models comprises ranking a first model higher than a second model based on a majority of the multiple scores indicating that the first model is better than the second model.

7. The method of claim 1, further comprising
selecting a first sample of the plurality of neural network models,
obtaining a first score indicative of validation loss for each model in the first sample,
ranking the models within the first sample based on the obtained first score,
selecting a second sample from the first sample,
obtaining a second score indicative of validation loss for each model in the second sample, and
ranking the models within the second sample based on the obtained second score,
wherein the first subset is selected from the ranked models within the second models and the first score and the second score are included in the at least one score.

8. The method of claim 1 comprising
obtaining the at least one score indicative of validation loss in the applying the searching algorithm and
basing the selection of a subsequent subset of the plurality of neural network models on the obtained scores.

9. The method of claim 8, wherein the obtaining the at least one score comprises calculating multiple scores for each model in the subset, and the method further comprises:
obtaining a performance metric for each model in the subset; and
comparing the obtained performance metric with each of the multiple scores to determine which of the multiple scores correlates with the obtained performance metric.

10. The method of claim 9, further comprising:
selecting one or more metrics based on the correlation,
wherein the selected one or more metrics are used to calculate a next score.

11. The method of claim 5 comprising:
obtaining the at least one score indicative of validation loss in the applying the search algorithm, and
selecting a subsequent subset of the plurality of neural network models based on the obtained scores.

12. The method of claim 11, wherein the at least one score indicative of validation loss for each model in the sample and the at least one score indicative of validation loss in the applying the search algorithm is calculated using at least one different metric.

13. The method of claim 1 comprising
obtaining the at least one score indicative of validation loss alongside the applying;
obtaining a performance metric for each model in the subset and
identifying the optimal neural network architecture using both the obtained at least one score and performance metric.

14. A server comprising:
a processor configured to:
obtain a plurality of neural network models;
select a first subset of the plurality of neural network models;
apply a searching algorithm to the selected subset of models; and
identify an optimal neural network architecture by repeating the selecting and applying for a fixed number of iterations;
wherein at least one score indicative of validation loss for each model is used in or alongside at least one of the selecting and applying.

15. A non-transitory computer-readable recording medium having recorded thereon a program which, when executed by a computer, causes the computer to perform operations comprising:
obtaining a plurality of neural network models;
selecting a first subset of the plurality of neural network models;
applying a searching algorithm to the selected subset of models; and
identifying an optimal neural network architecture by repeating the selecting and applying for a fixed number of iterations;
wherein at least one score indicative of validation loss for each model is used in or alongside at least one of the selecting and applying.
